(19) United States
(12) Patent Application Publication
(10) Pub. No.: US 2013/0112235 A1
(43) Pub. Date: May 9, 2013

(54) PHOTOELECTRIC CONVERSION DEVICE, METHOD OF MANUFACTURING PHOTOELECTRIC CONVERSION DEVICE, AND PHOTOELECTRIC CONVERSION MODULE

(71) Applicants: Satoshi Oomae, Omihachiman-shi (JP); Masato Fukudome, Omihachiman-shi (JP)

(72) Inventors: Satoshi Oomae, Omihachiman-shi (JP); Masato Fukudome, Omihachiman-shi (JP)

(73) Assignee: KYOCERA CORPORATION, Kyoto-shi, Kyoto (JP)

(21) Appl. No.: 13/808,735

(22) PCT Filed: Jul. 28, 2011
(86) PCT No.: PCT/JP2011/067231

§ 371 Date: Jan. 7, 2013

(30) Foreign Application Priority Data
Jul. 28, 2010 (JP) 2010-169473
Jul. 28, 2010 (JP) 2010-169477
Jan. 28, 2011 (JP) 2011-016001
Jan. 31, 2011 (JP) 2011-017449

(51) Int. Cl. H01L 31/042; H01L 31/0264; H01L 31/18

(52) U.S. Cl. CPC H01L 31/042; H01L 31/18; H01L 31/0264
USPC 136/244; 438/95; 136/252; 136/265

(57) ABSTRACT

It is an object of the present invention to provide a photoelectric conversion device and a photoelectric conversion module with enhanced conversion efficiency.

The photoelectric conversion device comprises: a light-absorbing layer containing a compound semiconductor capable of photoelectric conversion; and a semiconductor layer provided on one side of the light-absorbing layer and containing sulfur, wherein more sulfur is present in part of the semiconductor layer on the aforementioned light-absorbing layer side than in part thereof on the opposite side from the aforementioned light-absorbing layer.

### TECHNICAL FIELD

The present invention relates to a photoelectric conversion device, a method of manufacturing the photoelectric conversion device, and a photoelectric conversion module.

### BACKGROUND ART

Conventionally, a solar cell comprises a plurality of photoelectric conversion devices serving as constituent units thereof and each including a light-absorbing layer comprised of chalcopyrite CIGS and the like, the photoelectric conversion devices being connected in series or in parallel on a substrate made of glass and the like.

Such a photoelectric conversion device is provided with a buffer layer on a light receiving surface thereof, i.e. the light-absorbing layer. Used as the buffer layer is a zinc mixed crystal compound semiconductor film containing sulfur, for example, which is chemically grown from a solution by a solution deposition technique (CBD method) and the like for the purpose of obtaining a hetero junction suitable for the light-absorbing layer.

Also, a photoelectric conversion device disclosed in Japanese Patent Application Laid-Open No. 08-330614 (1996), for example, includes a zinc oxide film serving as a transparent electrode and provided on the buffer layer.

### SUMMARY OF INVENTION

However, there have been cases in which the photoelectric conversion device as disclosed in Japanese Patent Application Laid-Open No. 08-330614 (1996) and a photoelectric conversion module using the same do not stand up to use because of their conversion efficiency which is still low, depending on their application.

The present invention is accomplished to overcome the aforementioned problem with the prior art. It is therefore an object of the present invention to provide a photoelectric conversion device and a photoelectric conversion module with enhanced conversion efficiency.

A photoelectric conversion device according to one embodiment of the present invention is characterized by comprising: a light-absorbing layer containing a compound semiconductor capable of photoelectric conversion and a semiconductor layer provided on one side of the light-absorbing layer and containing sulfur, wherein more sulfur is present in part of the semiconductor layer on the aforementioned light-absorbing layer side than in part thereof on the opposite side from the aforementioned light-absorbing layer.

Further, a photoelectric conversion module according to one embodiment of the present invention is characterized by comprising a plurality of photoelectric conversion devices as described above, adjacent ones of the photoelectric conversion devices being electrically connected to each other.

Also, a method of manufacturing a photoelectric conversion device according to one embodiment of the present invention is characterized by comprising: forming a first semiconductor layer containing sulfur on a light-absorbing layer containing a compound semiconductor capable of photoelectric conversion by a wet film formation method using a film-forming solution having a first pH; and thereafter forming a second semiconductor layer containing less sulfur than the aforementioned first semiconductor layer by a wet film formation method using a film-forming solution having a pH which is more neutral than the aforementioned first pH, whereby a semiconductor layer is formed in which more sulfur is present in part thereof on the aforementioned light-absorbing layer side than in part thereof on the opposite side from the aforementioned light-absorbing layer. Alternatively, the method is characterized by comprising forming a film on a light-absorbing layer containing a compound semiconductor capable of photoelectric conversion by a wet film formation method using an acid or alkaline film-forming solution while changing the pH of the film-forming solution so as to be closer to neutrality, whereby a semiconductor layer is formed in which more sulfur is present in part thereof on the aforementioned light-absorbing layer side than in part thereof on the opposite side from the aforementioned light-absorbing layer.

The aforementioned embodiments allow the formation of a good pn junction between the light-absorbing layer and the semiconductor layer, and also provide good light permeability of the semiconductor layer to achieve good light incidence on the light-absorbing layer. This can provide the photoelectric conversion device and the photoelectric conversion module with enhanced conversion efficiency.

### BRIEF DESCRIPTION OF DRAWINGS

FIGS. 1A and 1B show embodiments of photoelectric conversion devices and a photoelectric conversion module according to the present invention, in which FIG. 1A is a sectional view showing one example thereof, and FIG. 1B is a sectional view showing another example thereof.

FIG. 2 is a perspective view of the embodiment of the photoelectric conversion devices and the photoelectric conversion module of FIG. 1B according to the present invention.

FIG. 3 shows a photograph as a substitute for a sectional view of a semiconductor layer (single-layer) and a light-absorbing layer according to one example of the present embodiment.

FIG. 4 shows a photograph as a substitute for a sectional view of a semiconductor layer (double-layer) and the light-absorbing layer according to one example of the present embodiment.

FIG. 5 is a graph showing a composition distribution of sulfur after heat treatment in the semiconductor layer (single-layer) and the light-absorbing layer according to one example of the present embodiment.

FIG. 6 is a graph showing a composition distribution of sulfur after heat treatment in the semiconductor layer (double-layer) and the light-absorbing layer according to one example of the present embodiment.

FIG. 7 is a graph showing a composition distribution of oxygen after heat treatment in the semiconductor layer (single-layer) and the light-absorbing layer according to one example of the present embodiment.

FIG. 8 is a graph showing a composition distribution of oxygen after heat treatment in the semiconductor layer (double-layer) and the light-absorbing layer according to one example of the present embodiment.

### DESCRIPTION OF EMBODIMENTS

One embodiment of a photoelectric conversion device, a method of manufacturing the same, and a photoelectric conversion module according to the present invention will be described in detail hereinafter with reference to the drawings.

(Photoelectric Conversion Device)

A photoelectric conversion device 10 includes a substrate 1, a first electrode layer 2, a light-absorbing layer 3, a semiconductor layer 4, and a second electrode layer 5.

In some cases, the semiconductor layer 4 includes a first semiconductor layer 4a on the light-absorbing layer 3 side, and a second semiconductor layer 4b on the second electrode layer 5 side. The semiconductor layer 4 refers to a layer which makes a hetero junction with the light-absorbing layer 3. The semiconductor layer 4 having a thickness on the order of 5 to 200 nm is formed on the light-absorbing layer 3. Preferably, the light-absorbing layer 3 and the semiconductor layer 4 are of different conductivity types. For example, when the light-absorbing layer 3 is a p type semiconductor, the semiconductor layer 4 is an n type semiconductor. From the viewpoint of decreasing leakage currents, it is preferable that the semiconductor layer 4 is a layer having a resistivity of not less than 1 Ω/cm. To enhance the light absorption efficiency of the light-absorbing layer 3, it is also preferable that the semiconductor layer 4 has light permeability to a wavelength range of light which the light-absorbing layer 3 absorbs.

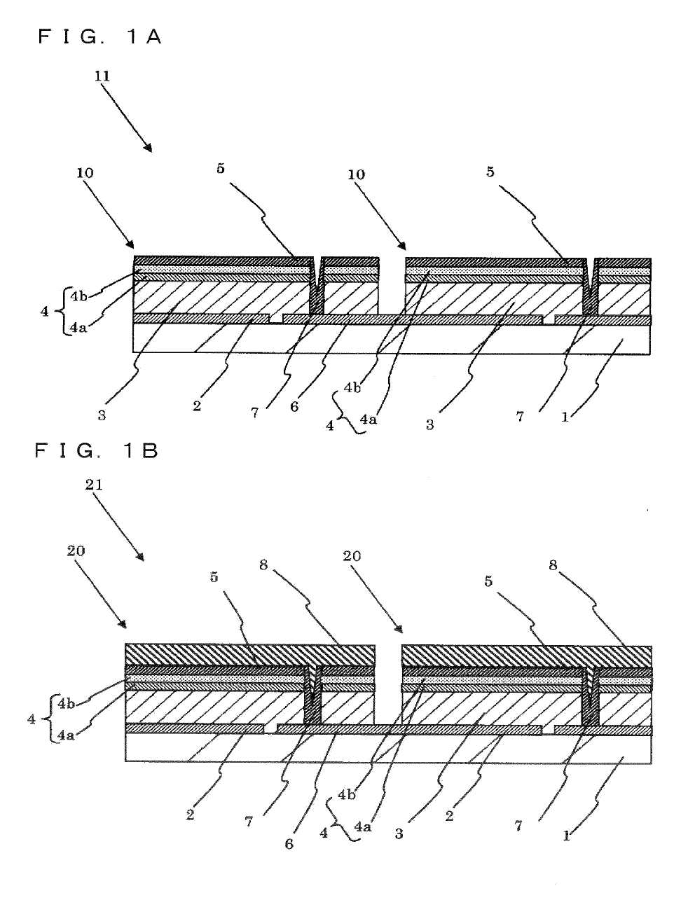

With reference to FIGS. 1A and 1B, a plurality of photoelectric conversion device 10 are arranged. Each of the photoelectric conversion devices 10 further includes a third electrode layer 6 provided on the substrate 1 side of the light-absorbing layer 3, the third electrode layer 6 being in spaced apart relation to the first electrode layer 2. A connection conductor 7 establishes an electrical connection between the second electrode layer 5 and the third electrode layer 6. This third electrode layer 6 is integral with the first electrode layer 2 of an adjacent one of the photoelectric conversion devices 10. In this configuration, adjacent ones of the photoelectric conversion devices 10 are connected in series with each other. In a single photoelectric conversion device 10, the connection conductor 7 is provided so as to extend through the light-absorbing layer 3 and the semiconductor layer 4, and a photoelectric conversion is performed by the light-absorbing layer 3 and the semiconductor layer 4 which are sandwiched between the first electrode layer 2 and the second electrode layer 5.

The substrate 1 is provided to support the photoelectric conversion devices 10. Examples of a material used for the substrate 1 include glass, ceramic, resin, metal and the like.

A conductor such as Mo, Al, Ti, Au or the like is used for the first electrode layer 2 and the third electrode layer 6. The first electrode layer 2 and the third electrode layer 6 are formed on the substrate 1 by a sputtering method, an evaporation method or the like.

The second electrode layer 5 is a transparent conductive film which is 0.05 to 3 μm and is comprised of ITO, ZnO and the like. The second electrode layer 5 is formed by a sputtering method, an evaporation method, a chemical vapor deposition (CVD) method, or the like. The second electrode layer 5 is a layer lower in resistivity than the semiconductor layer 4, and is configured to draw an electrical charge induced in the light-absorbing layer 3. From the viewpoint of drawing the electrical charge well, it is preferable that the second electrode layer 5 has a resistivity of less than 1 Ω/cm and a sheet resistance of not more than 50Ω/□ (ohms per square).

Preferably, the second electrode layer 5 has light permeability to light which the light-absorbing layer 3 absorbs for the purpose of enhancing the absorption efficiency of the light-absorbing layer 3. It is preferable that the second electrode layer 5 has a thickness of 0.05 to 0.5 μm from the viewpoints of enhancing the light permeability, enhancing the effect of preventing light reflection losses and the effect of scattering light, and transmitting the current produced by the photoelectric conversion well. It is also preferable that the second electrode layer 5 and the semiconductor layer 4 are approximately equal to each other in refractive index from the viewpoint of preventing the light reflection losses at an interface between the second electrode layer 5 and the semiconductor layer 4.

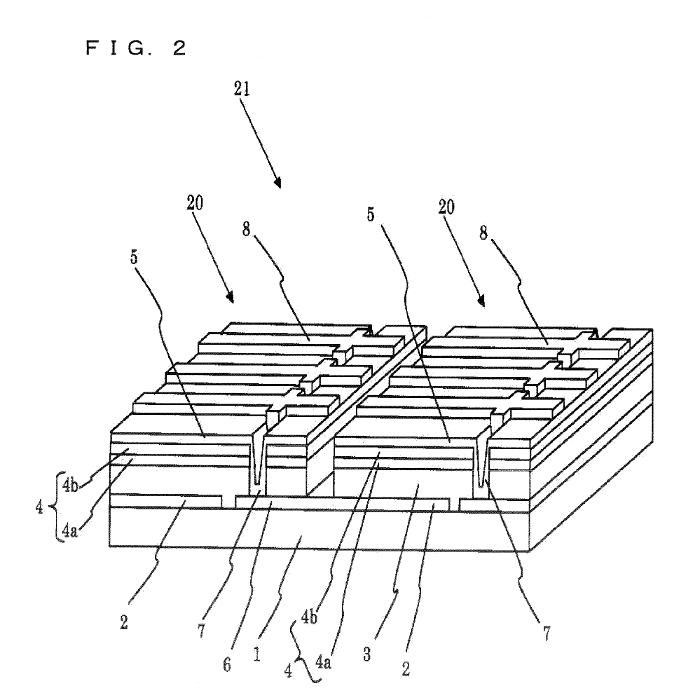

Next, another embodiment of the photoelectric conversion device according to the present invention will be described with reference to FIGS. 1B and 2. FIG. 1B is a sectional view of photoelectric conversion devices 20 according to the another embodiment, and FIG. 2 is a perspective view of the photoelectric conversion devices 20. FIGS. 1B and 2 differ from the photoelectric conversion devices 10 of FIG. 1A in that collecting electrodes 8 are formed on the second electrode layer 5. Like reference numerals and characters are used to designate components in FIGS. 1B and 2 similar to those in FIG. 1A. With reference to FIGS. 1A and 2, the photoelectric conversion devices 20 are connected to form a photoelectric conversion module 21 in a manner similar to that in FIG. 1A.

First, a semiconductor layer having a single-layer structure will be described as the semiconductor layer 4.

The semiconductor layer 4 includes sulfides such as Ga₂S₃, In₂S₃ and ZnS, for example. The semiconductor layer 4 is highly durable in high-temperature and high-humidity environments, and is less prone to degradation.

The photoelectric conversion device 10 according to the present embodiment includes the light-absorbing layer 3 containing a compound semiconductor capable of photoelectric conversion, and the semiconductor layer 4 provided on one side of the light-absorbing layer 3 and containing sulfur. More sulfur is present in part of the semiconductor layer 4 on the light-absorbing layer 3 side than in part thereof on the opposite side from the light-absorbing layer 3.

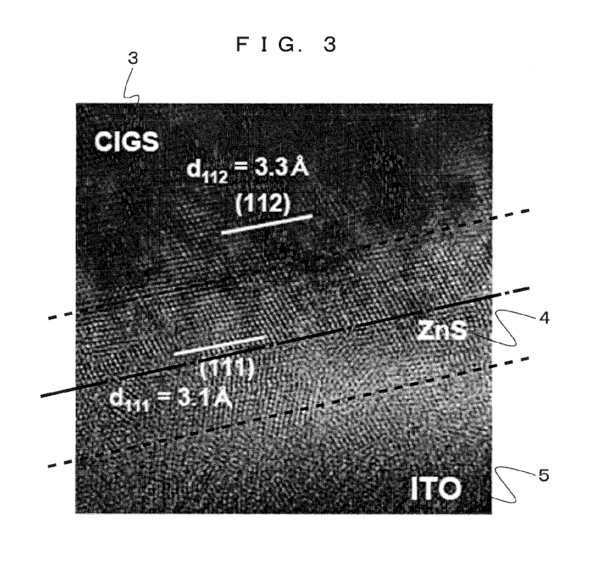

In FIG. 3, for example, a center line between an interface (broken line) between the semiconductor layer 4 and the light-absorbing layer 3 and an interface (broken line) between the second electrode layer 5 and the semiconductor layer 4 is indicated by a dash-dot line.

The positions of these interfaces are verified on a photomicrograph of TEM analysis because the semiconductor layer 4, the light-absorbing layer 3 and the second electrode layer 5 differ from each other in surface orientation.

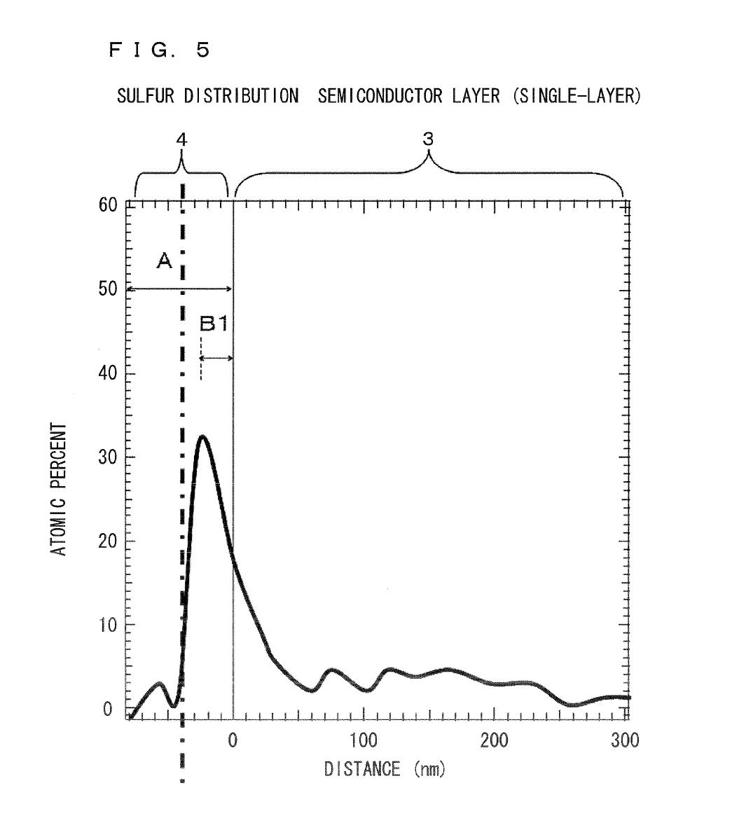

FIG. 5 is a graph showing the atomic percent of sulfur based on the total composition for the light-absorbing layer 3 and the semiconductor layer 4 (single-layer structure). It is found from FIG. 5 that sulfur is lopsided toward the light-absorbing layer 3 side with respect to the middle (dash-dot line) of the semiconductor layer 4 as seen in the direction of the thickness thereof. In other words, it is shown that sulfur is greater in proportion on the light-absorbing layer 3 side in the entire semiconductor layer 4.

Increasing sulfur in this manner on the side of the interface with the light-absorbing layer 3 in the semiconductor layer 4 allows the formation of a good pn junction between the light-absorbing layer 3 and the semiconductor layer 4. Also, decreasing sulfur on the opposite side from the light-absorbing layer 3 in the semiconductor layer 4 allows the increase in light permeability. This improves voltage to improve photoelectric conversion efficiency.

Further, it is preferable that the part of the semiconductor layer 4 on the light-absorbing layer 3 side in the present embodiment includes a region where the composition ratio of sulfur is maximized.

As shown in FIG. 5, for example, it is found that the maximum value of the composition ratio of sulfur is present in the part of the semiconductor layer 4 on the light-absorbing layer 3 side (near −30 nm). When the region where the composition ratio of sulfur is substantially maximized is present on the light-absorbing layer 3 side, the semiconductor layer 4 can be in such a condition that more sulfur is present in the part of the semiconductor layer 4 on the light-absorbing layer 3 side than in the part of the semiconductor layer 4 on the opposite side.

This makes it easy to increase the light permeability near the pn junction between the semiconductor layer 4 and the light-absorbing layer 3. In other words, this makes it easy for light to pass through to near the pn junction between the semiconductor layer 4 and the light-absorbing layer 3. As a result, the photoelectric conversion efficiency near the pn junction between the semiconductor layer 4 and the light-absorbing layer 3 can be enhanced.

Further, the present embodiment attains B1/A of not more than 0.4 where A is the thickness of the semiconductor layer 4 and B1 is a distance from the light-absorbing layer 3 to the region where the composition ratio of sulfur is maximized.

This range allows light to pass through to near the pn junction between the semiconductor layer 4 and the light-absorbing layer 3 more easily. Thus, the absorption of light near the pn junction between the semiconductor layer 4 and the light-absorbing layer 3 is increased more easily. As a result, the photoelectric conversion efficiency near the pn junction between the semiconductor layer 4 and the light-absorbing layer 3 is further enhanced.

Further, the thickness A of the semiconductor layer 4 is 25 to 100 nm according to the present embodiment.

This range allows light to pass through to near the pn junction between the semiconductor layer 4 and the light-absorbing layer 3 further easily. Thus, the absorption of light near the pn junction between the semiconductor layer 4 and the light-absorbing layer 3 is increased further easily.

Also, this range makes the band alignment with the light-absorbing layer 3 is made well, so that the charge separation function of a photoelectric conversion portion is enhanced.

Also, this range can contribute to the reduction in leakage current and suppress components serving as resistance to drawing current to enhance performance.

As a result of the foregoing, the aforementioned structure can further enhance the photoelectric conversion efficiency near the pn junction between the semiconductor layer 4 and the light-absorbing layer 3.

Further, it is preferable that the semiconductor layer 4 according to the present embodiment contains zinc.

Thus, zinc is diffused as an n-type dopant within the light-absorbing layer 3, so that a sulfide of the element zinc and a group III-B element (such as a Zn—In—S compound, for example) is formed on the surface side of the light-absorbing layer 3. This makes the pn junction with the light-absorbing layer 3 better to enhance the photoelectric conversion efficiency.

According to the present embodiment, more oxygen is present in the part of the semiconductor layer 4 on the opposite side from the light-absorbing layer 3 than in the part of the semiconductor layer 4 on the light-absorbing layer 3 side.

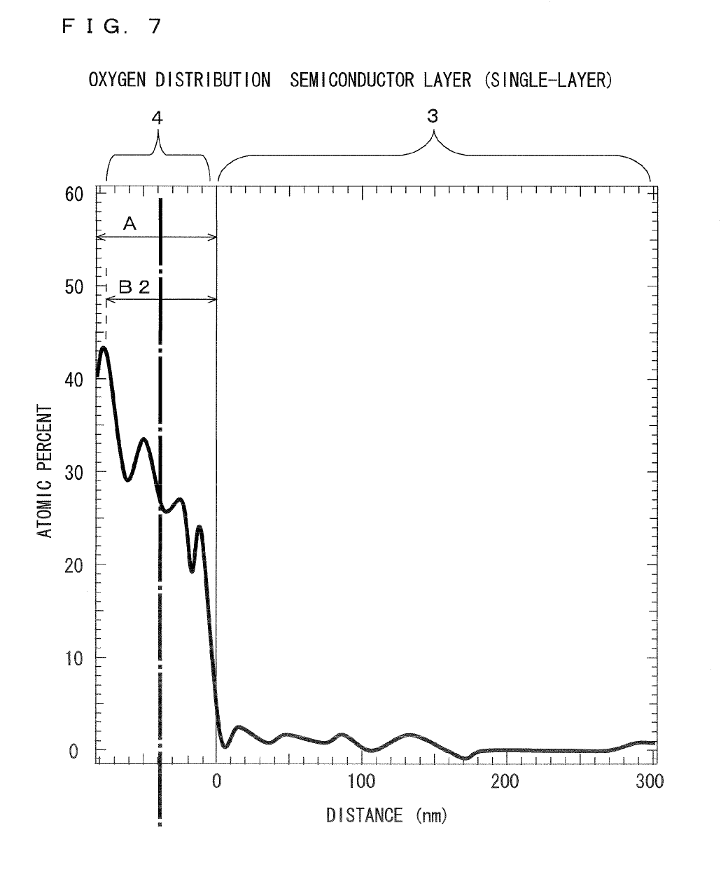

For example, FIG. 7 is a graph showing the atomic percent of oxygen based on the total composition for the light-absorbing layer 3 and the semiconductor layer 4 (single-layer structure). It is found from FIG. 7 that oxygen is lopsided toward the opposite side from the light-absorbing layer 3 with respect to the middle (dash-dot line) of the semiconductor layer 4 as seen in the direction of the thickness thereof. In other words, it is shown that oxygen is greater in proportion on the opposite side from the light-absorbing layer 3 in the entire semiconductor layer 4.

Suppressing the amount of oxygen in this manner on the side of the interface with the light-absorbing layer 3 in the semiconductor layer 4 allows the formation of a good pn junction between the light-absorbing layer 3 and the semiconductor layer 4. Also, increasing oxygen on the opposite side from the light-absorbing layer 3 in the semiconductor layer 4 allows the increase in light permeability. This improves voltage to improve photoelectric conversion efficiency.

Further, it is preferable that the part of the semiconductor layer 4 on the opposite side from the light-absorbing layer 3 in the present embodiment includes a region where the composition ratio of oxygen is maximized.

As shown in FIG. 7, for example, it is found that the maximum value of the composition ratio of oxygen is present in the part of the semiconductor layer 4 on the opposite side from the light-absorbing layer 3 (near −80 nm). When the region where the composition ratio of oxygen is substantially maximized is present on the opposite side from the light-absorbing layer 3, the semiconductor layer 4 can be in such a condition that more oxygen is present in the part of the semiconductor layer 4 on the opposite side from the light-absorbing layer 3 than in the part of the semiconductor layer 4 on the light-absorbing layer 3 side.

This makes it easy to increase the light permeability near the pn junction between the semiconductor layer 4 and the light-absorbing layer 3. In other words, this makes it easy for light to pass through to near the pn junction between the semiconductor layer 4 and the light-absorbing layer 3.

Further, this allows the region where the composition ratio of oxygen is maximized to be kept away from the interface between the light-absorbing layer 3 and the semiconductor layer 4 where recombination is most prone to occur.

As a result, the photoelectric conversion efficiency near the pn junction between the semiconductor layer 4 and the light-absorbing layer 3 is enhanced.

Further, the present embodiment attains B2/A in the range of 0.6 to 1 where A is the thickness of the semiconductor layer 4 and B2 is a distance from the light-absorbing layer 3 to the region where the composition ratio of oxygen is maximized.

This range allows light to pass through to near the pn junction between the semiconductor layer 4 and the light-absorbing layer 3 more easily. Thus, the absorption of light near the pn junction between the semiconductor layer 4 and the light-absorbing layer 3 is increased more easily.

Also, this allows the region where recombination is most prone to occur to be kept further away from the interface between the light-absorbing layer 3 and the semiconductor layer 4.

As a result, the photoelectric conversion efficiency near the pn junction between the semiconductor layer 4 and the light-absorbing layer 3 is further enhanced.

Further, the semiconductor layer 4 according to the present embodiment includes the first semiconductor layer 4a provided on one side of the light-absorbing layer and containing sulfur, and the second semiconductor layer 4b provided on one side of the first semiconductor layer 4a and containing sulfur different in composition from that of the first semiconductor layer 4a. Additionally, more sulfur in atomic percent is present in the first semiconductor layer 4a than in the second semiconductor layer 4b.

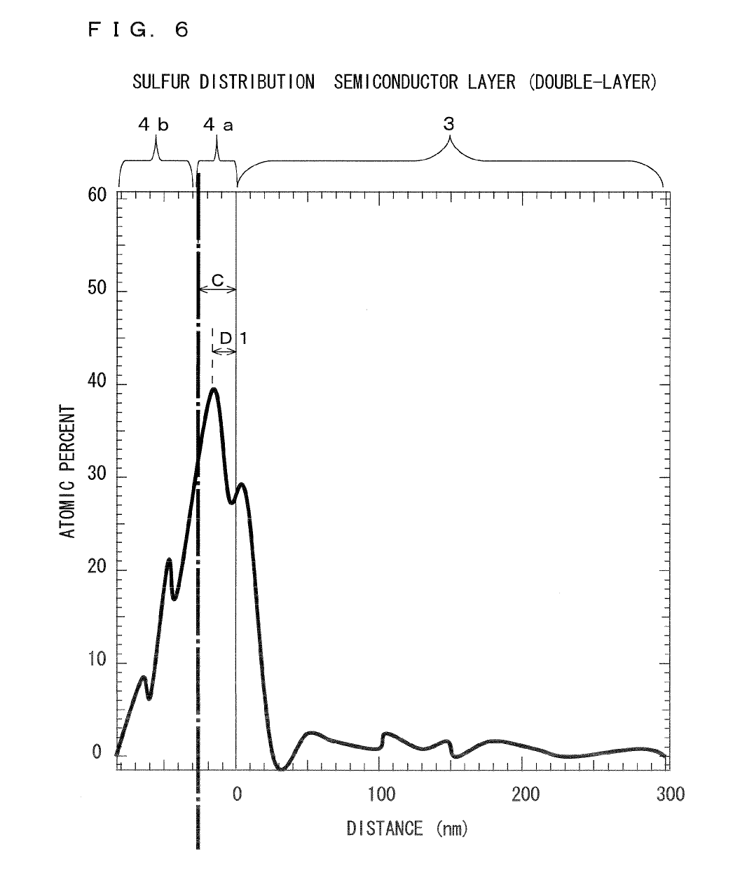

For example, FIG. 6 is a graph showing the atomic percent of sulfur based on the total composition for the light-absorbing layer 3 and the semiconductor layer 4 (double-layer structure). It is found from FIG. 6 that sulfur is eccentrically-located on the first semiconductor layer 4a side with respect to the interface (dash-dot line) between the first semiconductor layer 4a and the second semiconductor layer 4b, and more specifically that more sulfur is eccentrically-located in the first semiconductor layer 4a (in the range from 0 to −30 nm) than in the second semiconductor layer 4b (in the range from −30 to −80 nm). In other words, it is shown that sulfur is greater in proportion on the first semiconductor layer 4a side in the entire semiconductor layer 4.

The semiconductor layer 4 having a double-layer structure which contains a sulfide of a group III-B element as the first semiconductor layer 4a and zinc sulfide as the second semiconductor layer 4b will be described.

The first semiconductor layer 4a includes a semiconductor containing a sulfide of a group III-B element, examples of which include Ga₂S₃, In₂S₃ and the like. Such a semiconductor containing a sulfide of a group III-B element is highly durable in high-temperature and high-humidity environments, and is less prone to degradation.

Also, the second semiconductor layer 4b includes a semiconductor containing, for example, zinc sulfide. The semiconductor may contain a hydroxide of zinc and an oxide of zinc. Preferably, not less than 60% of the total number of moles of zinc constituting the second semiconductor layer 4b is zinc sulfide. Such a semiconductor containing zinc sulfide allows good band alignment with the light-absorbing layer 3 to enhance the photoelectric conversion efficiency. Also, such a semiconductor containing zinc sulfide enhances the durability of the second semiconductor layer 4b in high-temperature and high-humidity environments.

The structure in which the first semiconductor layer 4a and the second semiconductor layer 4b are sequentially stacked on the light-absorbing layer 3 provides both high durability in high-temperature and high-humidity environments and high photoelectric conversion efficiency. When a photoelectric conversion device having a large area is produced, this structure decreases variations in durability and in photoelectric conversion efficiency depending on the location. Thus, the increased area of the photoelectric conversion device excellent in durability and in photoelectric conversion characteristics is achieved.

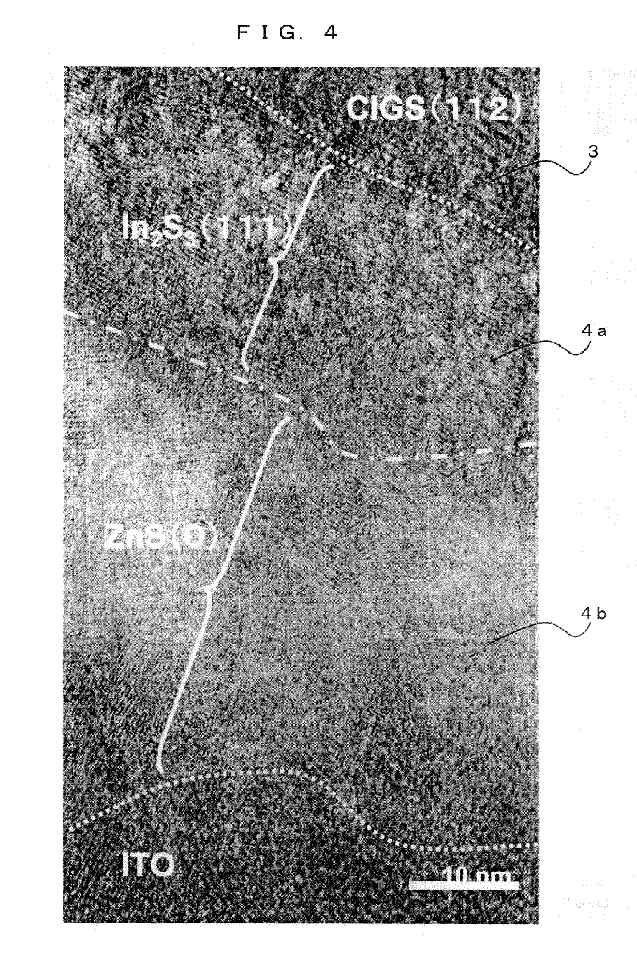

In FIG. 4, the interface between the first semiconductor layer 4a and the second semiconductor layer 4b is indicated by a dash-dot line.

The position of this interface is verified on a photomicrograph of TEM analysis because In₂S₃ (having a surface orientation (112) or (004)) and ZnS (having a surface orientation (111)) differ from each other in surface orientation. An observation was made under conditions of TEM analysis where an acceleration voltage was 200 kV and a CIGS surface was aligned with (112). In the case where In₂S₃ has not epitaxially grown to a surface contacting ZnS, a region where In(Indium) becomes not more than 10 atomic percent, for example, is determined as the interface between the first semiconductor layer 4a and the second semiconductor layer 4b.

Increasing sulfur in this manner on the first semiconductor layer 4a side allows the formation of a good pn junction between the light-absorbing layer 3 and the first semiconductor layer 4a. Also, decreasing sulfur on the second semiconductor layer 4b side allows the increase in light permeability. This improves voltage to improve the photoelectric conversion efficiency.

Further, it is preferable that the first semiconductor layer 4a, rather than the second semiconductor layer 4b, in the present embodiment includes a region where the composition ratio of sulfur is maximized.

As shown in FIG. 6, for example, it is found that the maximum value of the composition ratio of sulfur is present in the first semiconductor layer 4a (near −20 nm), rather than in the second semiconductor layer 4b. When the region where the composition ratio of sulfur is substantially maximized is present on the first semiconductor layer 4a side, such a condition that more sulfur is present in the first semiconductor layer 4a than in the second semiconductor layer 4b can be achieved.

This makes it easy to increase the light permeability of the second semiconductor layer 4b as compared with the first semiconductor layer 4a. In other words, this makes it easy for light to pass through to near the pn junction between the first semiconductor layer 4a and the light-absorbing layer 3. As a result, the photoelectric conversion efficiency near the pn junction between the first semiconductor layer 4a and the light-absorbing layer 3 is enhanced.

Further, the present embodiment attains D1/C in the range of 0 to 0.2 where C is the thickness of the aforementioned first semiconductor layer 4a and D1 is a distance from the aforementioned light-absorbing layer 3 to the aforementioned region where the composition ratio of sulfur is maximized.

This range allows light to pass through to near the pn junction between the first semiconductor layer 4a and the light-absorbing layer 3 more easily. Thus, the absorption of light near the pn junction between the first semiconductor layer 4a and the light-absorbing layer 3 is increased more easily. As a result, the photoelectric conversion efficiency near the pn junction between the first semiconductor layer 4a and the light-absorbing layer 3 is further enhanced. It should be noted that D1/C is outside the range of 0 to 0.2 in the graph of FIG. 6.

Further, the thickness C of the aforementioned first semiconductor layer 4a according to the present embodiment may be 50 to 150 nm.

This range allows light to pass through to near the pn junction between the first semiconductor layer 4a and the light-absorbing layer 3 further easily. Thus, the absorption of light near the pn junction between the first semiconductor layer 4a and the light-absorbing layer 3 is increased further easily.

Also, the band alignment with the light-absorbing layer 3 is made well, so that the charge separation function of the photoelectric conversion portion is enhanced.

This is preferable in that the photoelectric conversion efficiency can be further enhanced near the pn junction between the first semiconductor layer 4a and the light-absorbing layer 3.

Further, according to the present embodiment, the first semiconductor layer 4a and the second semiconductor layer 4b contain oxygen, and more oxygen in atomic percent is present in the second semiconductor layer 4b than in the first semiconductor layer 4a.

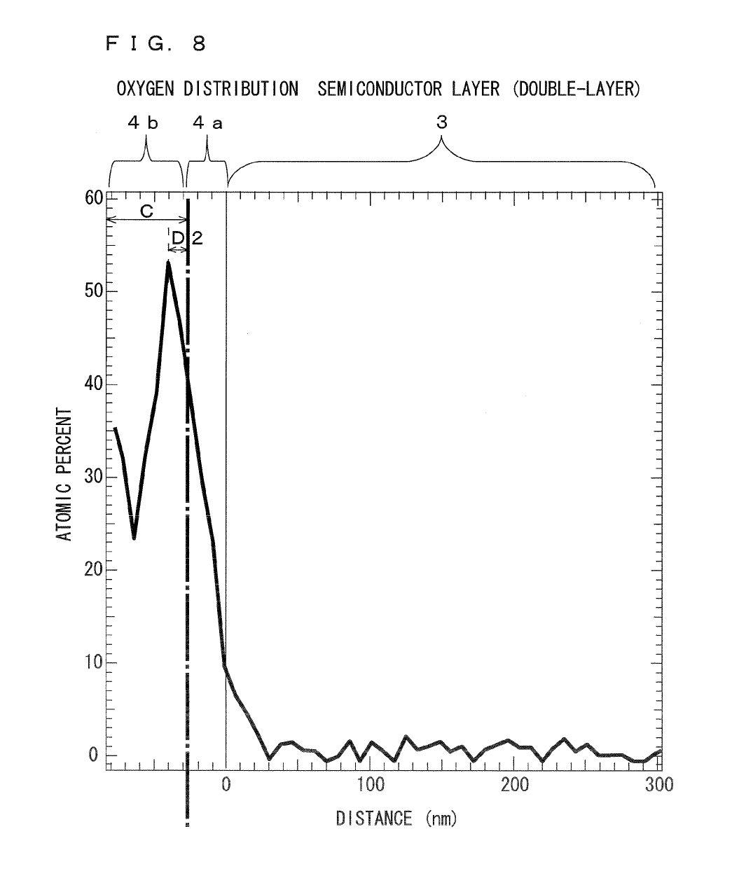

For example, FIG. 8 is a graph showing the atomic percent of oxygen based on the total composition for the light-absorbing layer 3 and the semiconductor layer 4 (double-layer structure). It is found from FIG. 8 that oxygen is eccentrically-located on the second semiconductor layer 4b side with respect to the interface (dash-dot line) between the first semiconductor layer 4a and the second semiconductor layer 4b, and more specifically that more oxygen is eccentrically-located in the second semiconductor layer 4b (in the range from −30 to −80 nm) than in the first semiconductor layer 4a (in the range from 0 to −30 nm). In other words, it is shown that oxygen is greater in proportion on the second semiconductor layer 4b side in the entire semiconductor layer 4.

Increasing oxygen in this manner on the second semiconductor layer 4b side to suppress oxygen relatively on the side of the interface between the first semiconductor layer 4a and the light-absorbing layer 3 allows the formation of a good pn junction between the light-absorbing layer 3 and the first semiconductor layer 4a. Also, increasing oxygen on the second semiconductor layer 4b side allows the increase in light permeability. This improves voltage to improve photoelectric conversion efficiency.

Further, it is preferable that the second semiconductor layer 4b, rather than the first semiconductor layer 4a, in the present embodiment includes a region where the composition ratio of oxygen is maximized.

As shown in FIG. 8, for example, it is found that the maximum value of the composition ratio of oxygen is present in the second semiconductor layer 4b (near −45 nm), rather than in the first semiconductor layer 4a. When the region where the composition ratio of oxygen is substantially maximized is present on the second semiconductor layer 4b side, such a condition that more oxygen is present in the second semiconductor layer 4b than in the first semiconductor layer 4a can be achieved.

This makes it easy to increase the light permeability of the second semiconductor layer 4b as compared with the first semiconductor layer 4a. In other words, this makes it easy for light to pass through to near the pn junction between the first semiconductor layer 4a and the light-absorbing layer 3.

Also, when the part on the opposite side from the light-absorbing layer 3 includes the region where the composition ratio of oxygen is maximized, a region where recombination is most prone to occur is kept away from the interface between the light-absorbing layer 3 and the semiconductor layer 4.

This is preferable in that the photoelectric conversion efficiency can be enhanced near the pn junction between the first semiconductor layer 4a and the light-absorbing layer 3.

Further, the present embodiment attains D2/C in the range of 0.6 to 1 where C is the thickness of the aforementioned second semiconductor layer 4b and D2 is a distance from the aforementioned first semiconductor layer 4a to the aforementioned region where the composition ratio of oxygen is maximized.

This range allows the region where the composition ratio of oxygen is maximized to be kept away from the interface between the first semiconductor layer 4a and the light-absorbing layer 3. This is more preferable because a good pn junction is formed between the light-absorbing layer 3 and the semiconductor layer 4.

This makes it easy to further increase the light permeability of the second semiconductor layer 4b as compared with the first semiconductor layer 4a.

Also, this allows the region where recombination is most prone to occur to be kept further away from the interface between the light-absorbing layer 3 and the semiconductor layer 4.

This is preferable in that the photoelectric conversion efficiency can be further enhanced near the pn junction between the first semiconductor layer 4a and the light-absorbing layer 3. It should be noted that D2/C is outside the range of 0.6 to 1 in the graph of FIG. 8.

Further, the thickness C of the aforementioned second semiconductor layer 4b is 10 to 100 nm according to the present embodiment.

This makes it easy to further increase the light permeability of the second semiconductor layer 4b as compared with the first semiconductor layer 4a.

Also, this allows the region where recombination is most prone to occur to be kept further away from the interface between the light-absorbing layer 3 and the semiconductor layer 4.

This is preferable in that the photoelectric conversion efficiency can be further enhanced near the pn junction between the first semiconductor layer 4a and the light-absorbing layer 3.

Further, the light-absorbing layer 3 according to the present embodiment preferably includes a chalcopyrite-based material, and has the function of absorbing light to create an electrical charge. The light-absorbing layer 3 is not particularly limited, but preferably includes a chalcopyrite-based compound semiconductor from the viewpoint of providing high photoelectric conversion efficiency even when it is a layer as thin as not more than 10 μm. An example of the chalcopyrite-based compound semiconductor includes a I-III-VI compound semiconductor. The I-III-VI compound semiconductor refers to a compound semiconductor (also referred to as a CIS-based compound semiconductor) formed by a group I-B element (also referred to as a group 11 element), a group III-B element (also referred to as a group 13 element), and a group VI-B element (also referred to as a group 16 element). Examples of the I-III-VI compound semiconductor include Cu(In,Ga)Se₂ (also referred to as CIGS), Cu(In,Ga)(Se,S)₂ (also referred to as CIGSS), and CuInSe₂ (also referred to as CIS). It should be noted that Cu(In,Ga)Se₂ refers to a compound composed mainly of Cu, In, Ga and Se. Also, Cu(In,Ga)(Se,S)₂ refers to a compound composed mainly of Cu, In, Ga, Se and S.

Such a light-absorbing layer 3 is formed by the following method. First, an element serving as a starting material (for example, a group I-B element, a group II-B element, a group III-B element, and a group VI-B element) is formed in the form of a film by sputtering and evaporation or is formed in the form of a film by coating with a starting material solution, whereby a precursor containing the element serving as a starting material is formed. Heating the precursor forms the light-absorbing layer 3 including a semiconductor. Alternatively, a metallic element (for example, a group I-B element, a group II-B element, and a group III-B element) may be formed in the form of a film in a manner similar to that described above to form a precursor, which in turn is heated in an atmosphere of gas containing a group VI-B element, whereby the light-absorbing layer 3 is formed.

(Photoelectric Conversion Module)

Further, a photoelectric conversion module 11 according to the present embodiment includes a plurality of photoelectric conversion devices 10, and is configured such that adjacent ones of the photoelectric conversion devices are electrically connected to each other.

Specifically, the plurality of photoelectric conversion devices 10 are arranged and electrically connected to form a photoelectric conversion module 11. For the purpose of connecting adjacent ones of the photoelectric conversion devices 10 in series easily, each of the photoelectric conversion devices 10 includes the third electrode layer 6 provided on the substrate 1 side of the light-absorbing layer 3, the third electrode layer 6 being in spaced apart relation to the first electrode layer 2, as shown in FIGS. 1A and 1B. The connection conductor 7 provided in the light-absorbing layer 3 establishes an electrical connection between the second electrode layer 5 and the third electrode layer 6.

The connection conductor 7 is preferably formed in the same step as forming the second electrode layer 5 and integrated with the second electrode layer 5. This simplifies the steps, and enhances the reliability of the electrical connection with the second electrode layer 5.

The connection conductor 7 is configured to connect the second electrode layer 5 and the third electrode layer 6 to each other, and also to divide the light-absorbing layers 3 of adjacent ones of the photoelectric conversion devices 10. This allows adjacent ones of the light-absorbing layers 3 to perform the photoelectric conversion well to draw current with a series connection.

(Method of Manufacturing Photoelectric Conversion Device)

A manufacturing method according to the present embodiment will be described hereinafter.

The semiconductor layer 4 is formed by a wet film formation method. The wet film formation method refers to a method for applying a starting material solution onto the light-absorbing layer 3 to cause the starting material solution to react chemically by treatment such as heating, and a method for causing precipitation on the light-absorbing layer 3 by a chemical reaction in a solution containing a starting material.

The use of such a method allows the diffusion of the semiconductor layer 4 to a certain extent into the surface of the light-absorbing layer 3 and the formation of the semiconductor layer 4 on the surface of the light-absorbing layer 3, thereby providing a good hetero junction with a small number of defects between the light-absorbing layer 3 and the semiconductor layer 4, when the semiconductor layer 4 has a single-layer structure, for example.

When the semiconductor layer 4 has a double-layer structure, for example, the first semiconductor layer 4a is diffused to a certain extent into the surface of the light-absorbing layer 3 and is formed on the surface of the light-absorbing layer 3, whereby a good hetero junction with a small number of defects is provided between the light-absorbing layer 3 and the semiconductor layer 4. Further, the second semiconductor layer 4b is diffused to a certain extent into the surface of the first semiconductor layer 4a and is formed on the surface of the first semiconductor layer 4a so that the second semiconductor layer 4b can come near the light-absorbing layer 3, whereby the band alignment between the light-absorbing layer 3 and the semiconductor layer 4 is improved.

A method of manufacturing the semiconductor layer 4 having the single-layer structure by the use of the aforementioned wet film formation method so that more sulfur is present on the light-absorbing layer 3 side will be presented hereinafter.

A film is formed on the light-absorbing layer containing a compound semiconductor capable of photoelectric conversion by a wet film formation method using an acid or alkaline film-forming solution while the pH of the film-forming solution is changed so as to be closer to neutrality, whereby the semiconductor layer 4 is formed in which more sulfur is present on the light-absorbing layer 3 side than the opposite part from the light-absorbing layer 3.

(Example of Semiconductor Layer 4 Having Same Composition System and Continuously Varying Composition Ratio in Thickness Direction)

When the semiconductor layer 4 includes a sulfide of a group III-B element such as Ga₂S₃ and In₂S₃, the pH of the film-forming solution shall be in the range of 1.5 to 2.8 using at least one acid selected from the group consisting of hydrochloric acid, acetic acid and nitric acid in the early stage of the film formation of the semiconductor layer 4 using the film-forming solution containing the group III-B element and sulfur. At the same time as the precipitation of the semiconductor layer 4, any one of a means of evaporating the acid from the film-forming solution at a temperature of 40° to 85° C., a means of adding warm water at 40° to 85° C. to the film-forming solution, and a means of adding an alkaline solution to the film-forming solution is used to control the pH of the film-forming solution so as to be closer to neutrality than 2.8, thereby forming the semiconductor layer 4. This forms the semiconductor layer 4 in which more sulfur is present in the part thereof on the light-absorbing layer 3 side.

For example, when the semiconductor layer 4 includes a sulfide of a group II-B element such as ZnS, the pH of the film-forming solution shall be not less than 9 using ammonia in the early stage of the film formation of the semiconductor layer 4 using the film-forming solution containing the group II-B element and sulfur. At the same time as the precipitation of the semiconductor layer 4, any one of a means of evaporating ammonia from the film-forming solution at a temperature of 70° to 90° C., a means of adding warm water at a temperature of 70° to 90° C. to the film-forming solution, and a means of adding an acid solution to the film-forming solution is used to control the pH of the aforementioned film-forming solution so as to be closer to the range of 6.5 to 7.5, thereby forming the semiconductor layer 4. This forms the semiconductor layer 4 in which more sulfur is present in the part thereof on the light-absorbing layer 3 side.

After the semiconductor layer 4 having the single-layer structure is formed by the aforementioned methods, it is preferable to further perform a heating treatment at 100° to 300° C., preferably at 150° to 250° C., on the semiconductor layer 4. This causes some diffusion of elements in the semiconductor layer 4, which in turn reduces defects in the semiconductor layer 4.

Next, a method of manufacturing the semiconductor layer 4 having the double-layer structure so that more sulfur is present on the light-absorbing layer 3 side will be presented hereinafter.

According to the present embodiment, the first semiconductor layer 4a containing sulfur is formed on the light-absorbing layer 3 containing a compound semiconductor capable of photoelectric conversion by a wet film formation method using a film-forming solution having a first pH, and thereafter the second semiconductor layer 4b containing less sulfur than the aforementioned first semiconductor layer 4a is formed by a wet film formation method using a film-forming solution having a second pH which is more neutral than the aforementioned first pH, whereby the semiconductor layer 4 is formed in which more sulfur is present in the part thereof on the aforementioned light-absorbing layer 3 side than in the opposite part from the aforementioned light-absorbing layer 3.

(Example of Semiconductor Layer 4 Having Same Composition System and Intermittently Varying Composition Ratio in Thickness Direction)

The first semiconductor layer 4a containing sulfur is formed on the light-absorbing layer 3 containing a compound semiconductor capable of photoelectric conversion by the wet film formation method using the film-forming solution having the first pH. Then, the second semiconductor layer 4b containing less sulfur than the first semiconductor layer 4a is formed on the first semiconductor layer 4a by the wet film formation method using the film-forming solution having the second pH which is more neutral than the first pH. This forms the semiconductor layer 4 in which more sulfur is present in the part thereof on the light-absorbing layer 3 side than in the opposite part from the light-absorbing layer 3. The method is not limited to the formation of the aforementioned first semiconductor layer 4a and the formation of the second semiconductor layer 4b. A third semiconductor layer, a fourth semiconductor layer and the like may be formed using a film-forming solution having a more neutral pH to provide the semiconductor layer 4 having three or more layers.

For example, when the semiconductor layer 4 includes a sulfide of a group III-B element such as Ga₂S₃ and In₂S₃, a first film is formed using the film-forming solution containing the group III-B element and sulfur which is an acid solution having the first pH (for example, a pH in the range of 1.5 to 2.8). Next, a second film is formed using the film-forming solution which is an acid solution having the second pH (for example, a pH in the range of 3.5 to 4.5) that is more neutral than the aforementioned first pH. This reduces the amount of sulfur contained in the second film.

For example, when the semiconductor layer 4 includes a sulfide of a group II-B element such as ZnS, the first film is formed using the film-forming solution containing the group II-B element and sulfur which is an alkaline solution having the first pH (for example, a pH in the range of 9 to 10). Next, the second film is formed using the film-forming solution which is an alkaline solution having the second pH (for example, a pH in the range of 6.5 to 7.5) that is more neutral than the aforementioned first pH. This reduces the amount of sulfur contained in the second film.

After the semiconductor layer 4 having the double-layer structure is formed by the aforementioned methods, it is preferable to further perform a heating treatment at 100° to 300° C., preferably at 150° to 250° C., on the semiconductor layer 4. This causes some diffusion of elements in the semiconductor layer 4, which in turn reduces defects in the semiconductor layer 4.

Alternatively, a heating treatment may be performed under the aforementioned conditions after the formation of the first semiconductor layer 4a, and thereafter a heating treatment may be performed again under the aforementioned conditions after the formation of the second semiconductor layer 4b. In such a case, the diffusion of elements is done better, which in turn further reduces defects at the interface between the light-absorbing layer 3 and the first semiconductor layer 4a and at the interface between the first semiconductor layer 4a and the second semiconductor layer 4b.

Also, at least one of the first semiconductor layer 4a and the second semiconductor layer 4b in the semiconductor layer 4 having the double-layer structure as mentioned above may be manufactured using the aforementioned method of manufacturing the semiconductor layer 4 having the single-layer structure. In this case, because a sulfur distribution is formed in the first semiconductor layer 4a or the second semiconductor layer 4b, a smoother sulfur distribution is provided in the entire semiconductor layer 4, and charge transfer becomes better.

Also, the present embodiment is not limited to the aforementioned manufacturing method. One of the first semiconductor layer 4a and the second semiconductor layer 4b may be formed by the method for causing precipitation in the solution, whereas the other is formed by the method for applying the starting material solution.

(Example of Semiconductor Layer 4 Having Different Composition Systems in Thickness Direction)

For example, in the semiconductor layer 4 having the double-layer structure, a metal sulfide of the first semiconductor layer 4a and a metal sulfide of the second semiconductor layer 4b may be different compounds. For example, the first semiconductor layer 4a may include a sulfide of a group III-B element such as Ga₂S₃ and In₂S₃, whereas the second semiconductor layer 4b may include a sulfide of a group II-B element such as ZnS. A manufacturing method in this case is as follows. First, the light-absorbing layer 3 is immersed in an aqueous solution containing the group III-B element and the element sulfur or an organic solvent based solution containing the group III-B element and the element sulfur, whereby the first semiconductor layer 4a containing the sulfide of the group III-B element is formed on the surface of the light-absorbing layer 3. Subsequently, this is immersed in an aqueous solution containing zinc and sulfur or an organic solvent based solution containing zinc and sulfur, whereby the second semiconductor layer 4b containing zinc sulfide is formed on the surface of the first semiconductor layer 4a so that a greater amount of sulfur is present in the first semiconductor layer 4a than in the second semiconductor layer 4b.

To put the amount (atomic percent) of sulfur of the first semiconductor layer 4a and the amount (atomic percent) of sulfur of the second semiconductor layer 4b in the aforementioned relationship, it is only necessary to adjust the pH during the film formation of the first semiconductor layer 4a and the pH during the film formation of the second semiconductor layer 4b as appropriate. For example, when the first semiconductor layer 4a includes Ga₂S₃ and In₂S₃ and the second semiconductor layer 4b includes ZnS, the amount of sulfur of the first semiconductor layer 4a is quantum-theoretically greater than that of the second semiconductor layer 4b. However, the amount of sulfur of the first semiconductor layer 4a may be made greater than that of the second semiconductor layer 4b when the distribution of sulfur is controlled aggressively and the control is exercised so that the pH during the formation of the first semiconductor layer 4a is smaller (higher in acidity) and the pH during the formation of the second semiconductor layer 4b is greater (higher in alkalinity).

A method of manufacturing the semiconductor layer 4 having the single-layer structure so that more oxygen is present on the opposite side from the light-absorbing layer 3 will be presented hereinafter.

Further, the present embodiment heat-treats the aforementioned semiconductor layer in an oxygen atmosphere after the aforementioned semiconductor layer is formed.

Specifically, after a film is formed on the light-absorbing layer 3 containing a compound semiconductor capable of photoelectric conversion by a wet film formation method, a heat treatment in an oxygen atmosphere causes oxygen to be introduced into the opposite side of the film from the light-absorbing layer 3, thereby forming the semiconductor layer 4 in which more oxygen is present in the part thereof on the opposite side from the light-absorbing layer 3 than in the part thereof on the light-absorbing layer 3 side.

The oxygen atmosphere used herein may have an oxygen partial pressure similar to that in air. More preferably, the oxygen atmosphere has an oxygen partial pressure of not less than 80%, the balance being nitrogen or an inert gas.

(Example of Semiconductor Layer 4 Having Same Composition System and Continuously Varying Composition Ratio in Thickness Direction)

The semiconductor layer 4 is formed on the light-absorbing layer 3 containing a compound semiconductor capable of photoelectric conversion by a wet film formation method using an acid or alkaline film-forming solution.

For example, when the semiconductor layer 4 includes a sulfide of a group III-B element such as Ga₂S₃ and In₂S₃, the pH of the film-forming solution shall be in the range of 1.5 to 2.8 using at least one acid selected from the group consisting of hydrochloric acid, acetic acid and nitric acid in the early stage of the film formation of the semiconductor layer 4 using the film-forming solution containing the group III-B element and sulfur. This suppresses the amount of oxygen in the part of the semiconductor layer 4 on the light-absorbing layer 3 side.

For example, when the semiconductor layer 4 includes a sulfide of a group II-B element such as ZnS, the pH of the film-forming solution shall be not less than 9 using ammonia in the early stage of the film formation of the semiconductor layer 4 using the film-forming solution containing the group II-B element and sulfur. This suppresses the amount of oxygen on the light-absorbing layer 3 side.

After the semiconductor layer 4 having the single-layer structure is formed by the aforementioned methods, a heating treatment at 100° to 300° C., preferably at 150° to 250° C., in an oxygen atmosphere is further performed on the semiconductor layer 4. This causes oxygen to be introduced into the semiconductor layer 4.

Next, a method of manufacturing the semiconductor layer 4 having the double-layer structure so that more oxygen is present on the opposite side from the light-absorbing layer 3 will be presented hereinafter.

(Example of Semiconductor Layer 4 Having Same Composition System and Intermittently Varying Composition Ratio in Thickness Direction)

The first semiconductor layer 4a is formed on the light-absorbing layer 3 containing a compound semiconductor capable of photoelectric conversion by a wet film formation method using a film-forming solution having the first pH. Then, the second semiconductor layer 4b is formed on this first semiconductor layer 4a by a wet film formation method using a film-forming solution different from the first film-forming solution. The method is not limited to the formation of the aforementioned first semiconductor layer 4a and the formation of the second semiconductor layer 4b. A third semiconductor layer, a fourth semiconductor layer and the like may be formed to provide the semiconductor layer 4 including three or more layers.

For example, when the semiconductor layer 4 includes a sulfide of a group III-B element such as Ga₂S₃ and In₂S₃, a first film is formed using a film-forming solution containing the group III-B element and sulfur and having a first composition. Next, a second film is formed using a film-forming solution of a different composition from the aforementioned first composition.

After the semiconductor layer 4 having the double-layer structure is formed by the aforementioned methods, a heating treatment at 100° to 300° C., preferably at 150° to 250° C., in an oxygen atmosphere is further performed on the semiconductor layer 4. This causes oxygen to be introduced into the semiconductor layer 4.

Also, at least one of the first semiconductor layer 4a and the second semiconductor layer 4b in the semiconductor layer 4 having the double-layer structure as mentioned above may be manufactured using the aforementioned method of manufacturing the semiconductor layer 4 having the single-layer structure.

(Example of Semiconductor Layer 4 Having Different Composition Systems in Thickness Direction)

For the semiconductor layer 4 having the double-layer structure, a metal compound of the first semiconductor layer 4a and a metal compound of the second semiconductor layer 4b may be different compounds.

For example, the first semiconductor layer 4a may include Ga₂S₃ and In₂S₃, whereas the second semiconductor layer 4b includes ZnS. A manufacturing method in this case is as follows. First, the light-absorbing layer 3 is immersed in an aqueous solution containing the group III-B element and the element sulfur or an organic solvent based solution containing the group III-B element and the element sulfur, whereby the first semiconductor layer 4a containing the sulfide of the group III-B element is formed on the surface of the light-absorbing layer 3. Subsequently, this is immersed in an aqueous solution containing zinc and sulfur or an organic solvent based solution containing zinc and sulfur, whereby the second semiconductor layer 4b containing zinc sulfide is formed on the surface of the first semiconductor layer 4a so that a greater amount of sulfur is present in the first semiconductor layer 4a than in the second semiconductor layer 4b.

After the semiconductor layer 4 having the double-layer structure in which the metal compound of the first semiconductor layer 4a and the metal compound of the second semiconductor layer 4b are different compounds is formed by the aforementioned methods, a heating treatment at 100° to 300° C., preferably at 150° to 250° C., in an oxygen atmosphere is further performed on the semiconductor layer 4. This causes oxygen to be introduced into the semiconductor layer 4.

The present embodiment is not limited to the aforementioned manufacturing method. One of the first semiconductor layer and the second semiconductor layer may be formed by the method for causing precipitation in the solution, whereas the other is formed by the method for applying the starting material solution.

### EXAMPLES

### Inventive Example 1

As the semiconductor layer 4, the semiconductor layer 4 containing an In—S compound was formed on the surface of the light-absorbing layer 3 by immersing the light-absorbing layer 3 in an aqueous solution containing the element In (indium) and the element sulfur. Specifically, the aqueous solution containing the element In (indium) and the element sulfur was a film-forming solution obtained by dissolving a salt containing the element In (indium) and a salt containing the element sulfur, the film-forming solution being adjusted to have a pH of 2 using an acid. This was controlled at a temperature of 60° C. to vaporize hydrochloric acid, and was finally controlled to have a pH of 3, so that the In—S compound having a predetermined thickness was formed.

Photoelectric conversion devices comprised of the aforementioned specimens were used to manufacture a photoelectric conversion module, and the photoelectric conversion efficiency thereof was evaluated.

The results were listed in Table 1 below.

TABLE 1

| | | | Distance from | | |
|---|---|---|---|---|---|
| | Proportion of | | light-absorbing | | |
| | sulfur on | | layer to region | | |
| | light-absorbing | | where | | |
| | layer side based | Thickness of | composition | Position where | |
| | on entire | semiconductor | ratio of sulfur is | composition | |
| | semiconductor | layer | maximized | ratio of sulfur is | Conversion |
| | layer | A | B1 | maximized | efficiency |
| | % | nm | nm | B1/A | % |
| 1 | 60 | 20 | 8 | 0.4 | 7 |
| 2 | 90 | 25 | 0 | 0 | 8 |
| 3 | 80 | 25 | 5 | 0.2 | 8 |
| 4 | 60 | 25 | 10 | 0.4 | 8 |
| 5 | 40 | 25 | 15 | 0.6 | 5 |
| 6 | 20 | 25 | 20 | 0.8 | 4 |
| 7 | 90 | 50 | 0 | 0 | 8 |
| 8 | 80 | 50 | 10 | 0.2 | 8 |
| 9 | 60 | 50 | 20 | 0.4 | 8 |
| 10 | 40 | 50 | 30 | 0.6 | 5 |
| 11 | 20 | 50 | 40 | 0.8 | 4 |
| 12 | 90 | 100 | 0 | 0 | 8 |
| 13 | 80 | 100 | 20 | 0.2 | 8 |
| 14 | 60 | 100 | 40 | 0.4 | 8 |
| 15 | 40 | 100 | 60 | 0.6 | 5 |
| 16 | 20 | 100 | 80 | 0.8 | 4 |
| 17 | 60 | 120 | 48 | 0.4 | 7 |

A is the thickness of the semiconductor layer, and B1 is a distance from the light-absorbing layer to a region where the composition ratio of sulfur is maximized.

For specimens 1 to 4, 7 to 9, 12 to 14, and 17 in Table 1, B1/A is not more than 0.4, so that the semiconductor layer 4 has more sulfur present on the light-absorbing layer 3 side. In this case, leakage current was difficult to generate, and the permeability of the semiconductor layer 4 was ensured. Therefore, good results showing photoelectric conversion efficiency of not less than 7% were obtained.

For specimens 5, 6, 10, 11, 15, and 16, B1/A is not less than 0.6, so that the semiconductor layer 4 has more sulfur present on the opposite side from the light-absorbing layer 3. In this case, photoelectric conversion efficiency was less than 5%.

Based on these results, the photoelectric conversion efficiency is high when the semiconductor layer 4 has more sulfur present on the light-absorbing layer 3 side. Particularly, the efficiency is higher when the thickness A of the semiconductor layer 4 is 25 to 100 nm and the distance B1 from the light-absorbing layer 3 to the region where the composition ratio of sulfur is maximized is 0 to 40 nm.

### Inventive Example 2

As the first semiconductor layer 4a, the first semiconductor layer 4a containing an In—S compound was formed on the surface of the light-absorbing layer 3 by immersing the light-absorbing layer 3 in an aqueous solution containing the element In (indium) and the element sulfur. Specifically, the aqueous solution containing the element In (indium) and the element sulfur was a film-forming solution obtained by dissolving a salt containing the element In (indium) and a salt containing the element sulfur, the film-forming solution being adjusted to have a pH of 2 using an acid. This was controlled at a temperature of 60° C. to vaporize hydrochloric acid, and was finally controlled to have a pH of 3, so that the In—S compound having each thickness was formed.

Subsequently, as the second semiconductor layer 4b, the second semiconductor layer 4b containing a Zn—S compound was formed on the surface of the first semiconductor layer 4a by immersing the first semiconductor layer 4a in an aqueous solution containing the element zinc and the element sulfur. Specifically, the aqueous solution containing the element zinc and the element sulfur was a film-forming solution obtained by dissolving a salt containing the element zinc and a salt containing the element sulfur, the film-forming solution being adjusted to have a pH of 13 using an alkali. This was controlled at a temperature of 80° C. to vaporize ammonia, and was finally controlled to have a pH of 7, so that the Zn—S compound having a thickness of 100 nm was formed. For the purpose of causing the first semiconductor layer 4a to have a greater amount of sulfur than the second semiconductor layer 4b, control is exercised whenever needed so that the pH during the formation of the first semiconductor layer 4a is smaller (higher in acidity) and the pH during the formation of the second semiconductor layer 4b is greater (higher in alkalinity).

Photoelectric conversion devices comprised of the aforementioned specimens were used to manufacture a photoelectric conversion module, and the photoelectric conversion efficiency thereof was evaluated.

The results were listed in Table 2 below.

TABLE 2

| | | Distance from | | |
|---|---|---|---|---|
| | | light-absorbing | Position | |
| | Thickness of | layer to region | where | |
| | first | where composition | composition | |
| | semiconductor | ratio of sulfur is | ratio | |
| | layer | maximized | of sulfur is | Conversion |
| | C | D1 | maximized | efficiency |
| | nm | nm | D1/C | % |
| 18 | 40 | 8 | 0.2 | 7 |
| 19 | 50 | 0 | 0 | 11 |
| 20 | 50 | 10 | 0.2 | 11 |
| 21 | 50 | 20 | 0.4 | 9 |
| 22 | 50 | 30 | 0.6 | 8 |
| 23 | 50 | 40 | 0.8 | 7 |
| 24 | 100 | 0 | 0 | 11 |
| 25 | 100 | 20 | 0.2 | 11 |
| 26 | 100 | 40 | 0.4 | 9 |
| 27 | 100 | 60 | 0.6 | 8 |
| 28 | 100 | 80 | 0.8 | 7 |
| 29 | 150 | 0 | 0 | 11 |
| 30 | 150 | 30 | 0.2 | 11 |
| 31 | 150 | 60 | 0.4 | 9 |
| 32 | 150 | 90 | 0.6 | 8 |
| 33 | 150 | 120 | 0.8 | 7 |
| 34 | 180 | 36 | 0.2 | 7 |

C is the thickness of the first semiconductor layer 4a, and D1 is a distance from the light-absorbing layer 3 to a region where the composition ratio of sulfur is maximized.

For all specimens 18 to 24 in Table 2, the first semiconductor layer 4a on the light-absorbing layer 3 side had more sulfur than the second semiconductor layer 4b, and good results showing photoelectric conversion efficiency of not less than 7% were obtained. In particular, the efficiency is higher when the thickness C of the first semiconductor layer 4 is 50 to 150 nm and the distance D1 from the light-absorbing layer 3 to the region where the composition ratio of sulfur is maximized is 0 to 30 nm.

### Inventive Example 3

As the first semiconductor layer 4a, the first semiconductor layer 4a containing an In—S compound was formed on the surface of the light-absorbing layer 3 by immersing the light-absorbing layer 3 in an aqueous solution containing the element In (indium) and the element sulfur. Specifically, the aqueous solution containing the element In (indium) and the element sulfur was a film-forming solution obtained by dissolving a salt containing the element In (indium) and a salt containing the element sulfur, the film-forming solution being adjusted to have a pH of 2 using an acid. This was controlled at a temperature of 60° C. to vaporize hydrochloric acid, and was finally controlled to have a pH of 3, so that the In—S compound having a thickness of 100 nm was formed.

Subsequently, as the second semiconductor layer 4b, the second semiconductor layer 4b containing a Zn—S compound was formed on the surface of the first semiconductor layer 4a by immersing the first semiconductor layer 4a in an aqueous solution containing the element zinc and the element sulfur. Specifically, the aqueous solution containing the element zinc and the element sulfur was a film-forming solution obtained by dissolving a salt containing the element zinc and a salt containing the element sulfur, the film-forming solution being adjusted to have a pH of 13 using an alkali. This was controlled at a temperature of 80° C. to vaporize ammonia, and was finally controlled to have a pH of 7, so that the Zn—S compound having each thickness was formed.

The films thus obtained were heat-treated at 200° C. in an atmosphere having an oxygen partial pressure of 80%.

Photoelectric conversion devices comprised of the aforementioned specimens were used to manufacture a photoelectric conversion module, and the photoelectric conversion efficiency thereof was evaluated.

The results were listed in Table 3 below.

TABLE 3

| | Proportion of | | | | |
|---|---|---|---|---|---|
| | amount of | | | | |
| | oxygen in | | Distance from | | |
| | second | | first | | |
| | semiconductor | | semiconductor | | |
| | layer | | layer to region | | |
| | based on | Thickness of | where | | |
| | amount of | second | composition | Position where | |
| | oxygen in entire | semiconductor | ratio of oxygen | composition | |
| | semiconductor | layer | is maximized | ratio of oxygen | Conversion |
| | layer | C | D2 | is maximized | efficiency |
| | % | nm | nm | D2/C | % |
| 35 | 60 | 5 | 3 | 0.6 | 8 |
| 36 | 55 | 10 | 2 | 0.2 | 7 |
| 37 | 60 | 10 | 4 | 0.4 | 8 |
| 38 | 70 | 10 | 6 | 0.6 | 12 |
| 39 | 80 | 10 | 8 | 0.8 | 12 |
| 40 | 90 | 10 | 10 | 1 | 12 |
| 41 | 55 | 50 | 10 | 0.2 | 7 |
| 42 | 60 | 50 | 20 | 0.4 | 8 |
| 43 | 70 | 50 | 30 | 0.6 | 12 |
| 44 | 80 | 50 | 40 | 0.8 | 12 |
| 45 | 90 | 50 | 50 | 1 | 12 |
| 46 | 55 | 100 | 20 | 0.2 | 7 |
| 47 | 60 | 100 | 40 | 0.4 | 8 |
| 48 | 70 | 100 | 60 | 0.6 | 12 |
| 49 | 80 | 100 | 80 | 0.8 | 12 |
| 50 | 90 | 100 | 100 | 1 | 12 |
| 51 | 60 | 120 | 72 | 0.6 | 8 |

C is the thickness of the second semiconductor layer 4b, and D2 is a distance from the first semiconductor layer 4a to a region where the composition ratio of oxygen is maximized.

For all specimens 35 to 51 in Table 3, the first semiconductor layer 4a on the light-absorbing layer 3 side had more sulfur than the second semiconductor layer 4b, and good results showing photoelectric conversion efficiency of not less than 7% were obtained. In particular, it is found that the efficiency is higher when the thickness C of the second semiconductor layer 4b is 10 to 100 nm and the distance D2 from the first semiconductor layer 4a to the region where the composition ratio of oxygen is maximized is 6 to 100 nm.

### Comparative Example

For Comparative Example, a chalcopyrite-based CIGS film was used as the light-absorbing layer 3, and the semiconductor layer 4 containing an In—S compound was formed as the semiconductor layer 4 on the surface of the light-absorbing layer 3 by immersing the light-absorbing layer 3 in an aqueous solution containing the element In (indium) and the element sulfur. The aqueous solution containing the element In (indium) and the element sulfur was a film-forming solution obtained by dissolving a salt containing the element In (indium) and a salt containing the element sulfur, the film-forming solution being controlled to have a pH of 2 using an acid. A photoelectric conversion device was formed in which an ITO film was provided as the second electrode layer 5.

Comparative Example is the photoelectric conversion device in which the semiconductor layer 4 is formed using the film-forming solution controlled to have a pH of 2, whereby the rates of content of sulfur and oxygen in the direction of the thickness of the semiconductor layer 4 are substantially constant. In Comparative Example, the conversion efficiency was not more than 3%.

This is considered to be due to the facts that less sulfur at the interface between the light-absorbing layer 3 and the semiconductor layer 4 does not contribute to the pn junction and that more oxygen at the interface between the light-absorbing layer 3 and the semiconductor layer 4 hinders the pn junction.

### REFERENCE SIGNS LIST

1 Substrate
2 First electrode layer
3 Light-absorbing layer
4 Semiconductor layer
   4a First semiconductor layer
   4b Second semiconductor layer
5 Second electrode layer
6 Third electrode layer
7 Connection conductor
8 Collecting electrodes
10, 20 Photoelectric conversion devices
11, 21 Photoelectric conversion modules

1. A photoelectric conversion device comprising:
a light-absorbing layer containing a compound semiconductor capable of photoelectric conversion; and
a semiconductor layer provided on one side of the light-absorbing layer and containing sulfur,
wherein more sulfur is present in part of the semiconductor layer on the light-absorbing layer side than in part thereof on the opposite side from the light-absorbing layer.

2. The photoelectric conversion device according to claim 1, wherein the part of the semiconductor layer on the light-absorbing layer side includes a region where the composition ratio of sulfur is maximized.

3. The photoelectric conversion device according to claim 2, wherein B1/A is 0 to 0.4 where A is the thickness of the semiconductor layer and B1 is a distance from the light-absorbing layer to the region where the composition ratio of sulfur is maximized.

4. The photoelectric conversion device according to claim 3, wherein the thickness A of the semiconductor layer is 25 to 100 nm.

5. The photoelectric conversion device according to claim 1, wherein the semiconductor layer contains zinc.

6. The photoelectric conversion device according to claim 1, wherein the semiconductor layer further contains oxygen, and more oxygen is present in the part of the semiconductor layer on the opposite side from the light-absorbing layer than in the part thereof on the light-absorbing layer side.

7. The photoelectric conversion device according to claim 6, wherein the part of the semiconductor layer on the opposite side from the light-absorbing layer includes a region where the composition ratio of oxygen is maximized.

8. The photoelectric conversion device according to claim 7, wherein B2/A is 0.6 to 1 where A is the thickness of the semiconductor layer and B2 is a distance from the light-absorbing layer to the region where the composition ratio of oxygen is maximized.

9. The photoelectric conversion device according to claim 1,
wherein the semiconductor layer includes
a first semiconductor layer provided on one side of the light-absorbing layer and containing sulfur, and
a second semiconductor layer provided on one side of the first semiconductor layer and containing sulfur different in composition from that of the first semiconductor layer, and
wherein more sulfur is present in the first semiconductor layer than in the second semiconductor layer.

10. The photoelectric conversion device according to claim 9, wherein the first semiconductor layer, rather than the second semiconductor layer, includes a region where the composition ratio of sulfur is maximized.

11. The photoelectric conversion device according to claim 9, wherein the first semiconductor layer and the second semiconductor layer contain oxygen, and more oxygen is present in the second semiconductor layer than in the first semiconductor layer.

12. The photoelectric conversion device according to claim 11, wherein the second semiconductor layer, rather than the first semiconductor layer, includes a region where the composition ratio of oxygen is maximized.

13. A photoelectric conversion module comprising
a plurality of photoelectric conversion devices as recited in claim 1, adjacent ones of the photoelectric conversion devices being electrically connected to each other.

14. A method of manufacturing a photoelectric conversion device, comprising:
forming a semiconductor layer on a light-absorbing layer containing a compound semiconductor capable of photoelectric conversion by a wet film formation method using an acid or alkaline film-forming solution while changing the pH of the film-forming solution so as to be closer to neutrality.

15. A method of manufacturing a photoelectric conversion device, comprising:
forming a first semiconductor layer containing sulfur on a light-absorbing layer containing a compound semiconductor capable of photoelectric conversion by a wet film formation method using a film-forming solution having a first pH; and
thereafter forming a second semiconductor layer containing less sulfur than the first semiconductor layer by a wet film formation method using a film-forming solution having a second pH which is more neutral than the first pH.
